(19) United States
(12) Patent Application Publication
(10) Pub. No.: US 2025/0366020 A1
(43) Pub. Date: Nov. 27, 2025

(54) PDSOI TRANSISTOR AND METHOD FOR FABRICATING SAME

(71) Applicant: Hangzhou HFC Semiconductor Co., Hangzhou (CN)

(72) Inventors: Yongsheng YANG, Shanghai (CN); Pengpeng WANG, Hangzhou (CN); Haijiang YUAN, Shanghai (CN); Chungchiang LIN, Hangzhou (CN)

(21) Appl. No.: 18/732,960

(22) Filed: Jun. 4, 2024

(30) Foreign Application Priority Data
May 24, 2024 (CN) 202410651280.6

(51) Int. Cl. H01L 29/78; H01L 21/225; H01L 21/762; H01L 29/167; H01L 29/417

(52) U.S. Cl. CPC H10D 30/637; H01L 21/2253; H01L 21/76243; H10D 62/834; H10D 64/258

(57) ABSTRACT

A partially depleted silicon-on-insulator (PDSOI) transistor and a method for fabricating the PDSOI transistor are disclosed. In PDSOI transistor, a first space is provided between a bottom surface of a source and a top surface of a buried oxide layer, and a second space is provided between a bottom surface of a drain and the top surface of the buried oxide layer. Moreover, a source contact structure extends into the source and a third space is provided between the source contact structure and the top surface of the buried oxide layer. With this configuration, electric charge can be picked up from the body region through the third space and the source contact structure, thereby avoiding the problem of the floating body effect (FBE) and enabling the PDSOI transistor to have improved quality and reliability.

### CROSS-REFERENCE TO RELATED APPLICATION

This application claims the priority of Chinese patent application number 202410651280.6, filed on May 24, 2024 and entitled “PDSOI TRANSISTOR AND METHOD FOR FABRICATING SAME”, the entire contents of which are incorporated herein by reference.

### TECHNICAL FIELD

The present invention relates to the field of semiconductor technology, and in particular, to a partially depleted silicon-on-insulator (PDSOI) transistor and a method for fabricating the PDSOI transistor.

### BACKGROUND

Silicon-on-insulator (SOI) is a type of silicon material with a special structure. SOI technology has been vastly investigated in various aspects, such as materials, devices and integrated circuits (IC) fabrication techniques. As this technology is capable of complete dielectric isolation, it provides a variety of advantages such as high reliability, a fast speed, low power consumption and a high degree of integration.

The physical properties of an SOI transistor are closely related to the thickness of its top silicon layer. SOI transistors can be categorized into partially depleted (PD) ones and fully depleted (FD) ones, by the type of their top silicon layer.

Although PDSOI transistors are more popular nowadays, they are associated with a particular problem, known as the floating body effect (FBE), due to a partially depleted active body region of the PDSOI transistors, the active body region is floating and charge carriers created by collisional ionization cannot rapidly migrate away. This may cause a range of issues with such devices, such as threshold voltage shifting, parasitic bipolar transistor effects, the kink effect, reduced output resistance in the saturation region and transient changes in the drain current. Consequently, they may suffer from a lower gain, noise overshoot, instable operation, a reduced source-drain breakdown voltage, single transistor latch-up, a considerable leakage current and increased power consumption. All these place limitations on the development of PDSOI transistors and circuits.

### SUMMARY OF THE INVENTION

It is an object of the present invention to provide a PDSOI transistor and a method for fabricating the transistor, which overcome the problem of floating body effect associated with conventional PDSOI transistors.

To this end, the present invention provides a PDSOI transistor, which comprises:
an SOI substrate comprising a bottom silicon layer, a buried oxide layer formed on the bottom silicon layer and a top silicon layer formed on the buried oxide layer;
a gate structure formed on the SOI substrate;
a source and a drain formed in the top silicon layer on opposite sides of the gate structure, wherein a first space is provided between a bottom surface of the source and a top surface of the buried oxide layer and wherein a second space is provided between a bottom surface of the drain and the top surface of the buried oxide layer; and
a source contact structure and a drain contact structure, wherein the source contact structure is connected to the source, wherein the drain contact structure is connected to the drain, and wherein the source contact structure extends into the source and a third space is provided between the source contact structure and the top surface of the buried oxide layer.

The present invention also provides a method for fabricating a PDSOI transistor, which comprises:
providing an SOI substrate, wherein the SOI substrate comprises a bottom silicon layer, a buried oxide layer formed on the bottom silicon layer and a top silicon layer formed on the buried oxide layer;
forming a gate structure on the SOI substrate;
forming a source and a drain in the SOI substrate, wherein the source and the drain are formed in the top silicon layer on opposite sides of the gate structure, wherein a first space is provided between a bottom surface of the source and a top surface of the buried oxide layer, and wherein a second space is provided between a bottom surface of the drain and the top surface of the buried oxide layer;
forming an interlayer dielectric layer on the SOI substrate, wherein the interlayer dielectric layer covers each of the gate structure and the SOI substrate; and
forming a source contact structure and a drain contact structure in the interlayer dielectric layer, wherein the source contact structure is connected to the source, wherein the drain contact structure is connected to the drain, and wherein the source contact structure extends into the source and a third space is provided between the source contact structure and the top surface of the buried oxide layer.

In the PDSOI transistor and method of the present invention, a first space is provided between the bottom surface of the source and the top surface of the buried oxide layer, and a second space is provided between the bottom surface of the drain and the top surface of the buried oxide layer. The source contact structure extends into the source and a third space is provided between the top surface of the buried oxide layer and the source contact structure. With this configuration, electric charge can be picked up from the body region through the third space and the source contact structure, thereby avoiding the FBE problem and enabling the PDSOI transistor to have improved quality and reliability.

### BRIEF DESCRIPTION OF THE DRAWINGS

FIGS. 1 to 5 show schematic cross-sectional views of intermediate structures resulting from process steps in a method for fabricating a PDSOI transistor according to embodiments of the present invention.

### LIST OF REFERENCE NUMERALS

100: SOI substrate; 101: bottom silicon layer; 102: buried oxide layer; 103: top silicon layer; 104: isolation structure; 110: gate structure; 111: gate dielectric layer; 112: conductive layer; 113: TiN layer; 120: first dielectric layer; 130: lightly doped source region; 131: lightly doped drain region; 140: second dielectric layer; 150: spacer; 160: source; 161: drain; 170: interlayer dielectric layer; 171: first opening; 172: second opening; 180: patterned photoresist layer; 190: source contact structure; 191: drain contact structure; 10: PDSOI transistor;
S1: first space; S2: second space; S3: third space.

### DETAILED DESCRIPTION

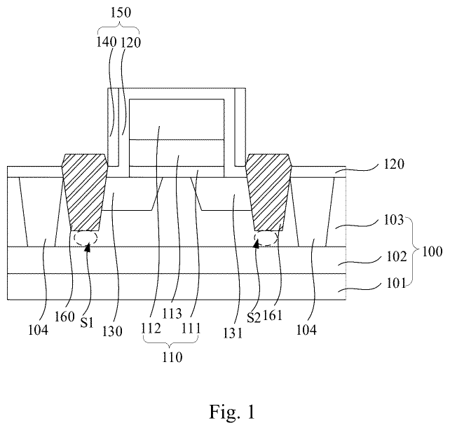

FIGS. 1 to 5 show schematic cross-sectional views of intermediate structures resulting from process steps in a method for fabricating a PDSOI transistor according to embodiments of the present invention.

As shown in FIG. 1, an SOI substrate 100 is provided, which includes a bottom silicon layer 101, a buried oxide layer 102 formed on the bottom silicon layer 101 and a top silicon layer 103 formed on the buried oxide layer 102. Preferably, the top silicon layer 103 has a thickness greater than 15 nm. In the SOI substrate 100, a plurality of isolation structures 104 are formed, so as to form a plurality of device regions. In the figures, only two isolation structures 104 are schematically shown. The isolation structures 104 extend from a surface of the top silicon layer 103 to a top surface of the buried oxide layer 102. The isolation structures 104 may be made of, for example, silicon oxide or the like.

With continued reference to FIG. 1, a gate structure 110 is then formed on the SOI substrate 100. The gate structure 110 includes a gate dielectric layer 111 and a conductive layer 112 formed on the gate dielectric layer 111. The gate dielectric layer 111 may be a high dielectric constant (k>3.9) material, or a low dielectric constant (k≤3.9) material. The conductive layer 112 may be polysilicon. Between the gate dielectric layer 111 and the conductive layer 112, there may be formed a titanium nitride (TiN) layer 113, which can enhance the quality and reliability of the resulting gate structure 110.

In embodiments of the present application, a first dielectric layer 120 may be formed on the SOI substrate 100, which covers both the SOI substrate 100 and the gate structure110. The first dielectric layer 120 may be formed of, for example, silicon oxide, silicon nitride or the like. The first dielectric layer 120 can provide protection to the SOI substrate 100 and the gate structure110 in the subsequent processes.

Subsequently, an ion implantation process is performed on the SOI substrate 100 to form a lightly doped source region 130 and a lightly doped drain region 131 in the SOI substrate 100. Each of the lightly doped source region 130 and the lightly doped drain region 131 extends from the top silicon layer 103 under the gate structures 110 to the top silicon layer 103 beside the gate structure 110.

With continued reference to FIG. 1, a second dielectric layer 140 is formed over opposite side walls of each gate structure 110. The second dielectric layer 140 covers the first dielectric layer 120 on the opposite side walls of the gate structure 110. The first dielectric layer 120 and the second dielectric layer 140 on the side walls of the gate structure 110 form spacers 150. The first dielectric layer 120 and the second dielectric layer 140 may be made of the same material, or different materials. For example, the first dielectric layer 120 may be formed of silicon oxide, and the second dielectric layer 140 may be formed of silicon nitride.

Next, a source 160 and a drain 161 are formed in the top silicon layer 103 on opposite sides of the gate structure 110. In specific embodiments of the present application, the source 160 and the drain 161 may be formed in the top silicon layer 103 external to the spacers 150. Further, each of the source 160 and the drain 161 may be contiguous with a corresponding isolation structure 104 in order to allow electric charge to be subsequently picked up.

Both the source 160 and the drain 161 extend from the surface of the top silicon layer 103 into the top silicon layer 103. A first space S1 is provided between a bottom surface of the source 160 and the top surface of the buried oxide layer 102, and a second space S2 is provided between a bottom surface of the drain 161 and the top surface of the buried oxide layer 102. Preferably, each of the first space S1 and the second space S2 has a dimension measured in a thickness direction of the SOI substrate 100, which is greater than 5 nm. Preferably, the dimensions of the first space S1 and the second space S2 in the thickness direction of the SOI substrate 100 are equal.

The source 160 and the drain 161 may be formed by an ion implantation process and/or an epitaxy process. In the latter case, openings may be formed in the top silicon layer 103 external to the spacers 150, and the source 160 and the drain 161 may be then epitaxially grown in the openings. Further, the source 160 and the drain 161 may protrude a surface of the SOI substrate 100, and a salicide layer (not shown) may be formed on surfaces of the source 160 and the drain 161 to enable electrical connection.

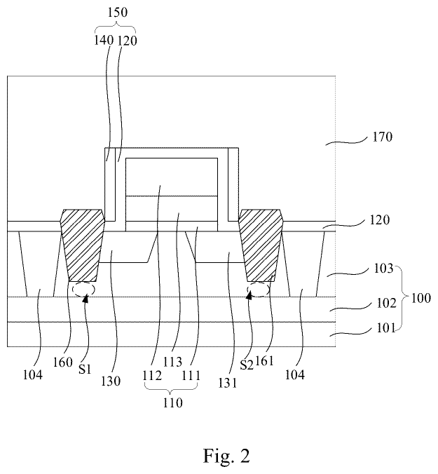

Afterwards, as shown in FIG. 2, an interlayer dielectric layer 170 is formed over the SOI substrate 100, which covers both the gate structure 110 and the SOI substrate 100. The interlayer dielectric layer 170 may be formed of, for example, silicon oxide by a deposition process.

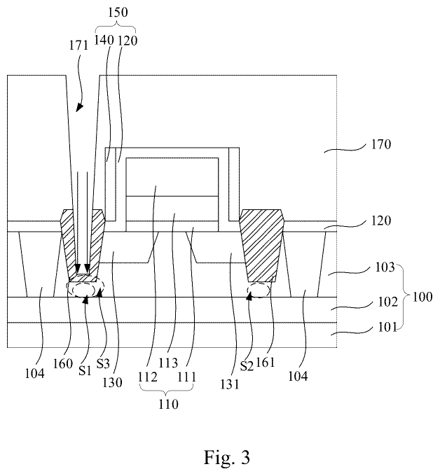

As shown in FIG. 3, in embodiments of the present application, a first opening 171 is formed in the interlayer dielectric layer 170. The first opening 171 penetrates through the interlayer dielectric layer 170 and extends into the source 160. A third space S3 is provided between a bottom surface of the first opening 171 and the top surface of the buried oxide layer 102. The third space S3 may include the first space S1 and a portion of the source 160 under the first opening 171. In other embodiments of the present application, the third space S3 may consist of only the first space S1. Preferably, the third space S3 has a dimension measured in the thickness direction of the SOI substrate 100, which ranges from 5 nm to 15 nm. That is, the dimension is greater than or equal to 5 nm and less than or equal to 15 nm. For example, it may be 7 nm, 10 nm, 12 nm, or the like.

Further, ions are implanted into the third space S3 through the first opening 171, so that the third space S3 comprises doping ions. In case of an NMOS device, the doping ions may be boron. In case of a PMOS device, the doping ions may be phosphorus. Preferably, when the doping ions are boron, the ions may be implanted at an energy of 2 KeV to 4 KeV and a dose of 1.0e15 cm⁻² to 2.0e15 cm⁻². When the doping ions are phosphorus, the ions may be implanted at an energy of 4 KeV to 8 KeV and a dose of 1.0e15 cm⁻² to 2.0e15 cm⁻².

Thereafter, an annealing process is performed on the third space S3 that has experienced the ion implantation process. Preferably, a laser annealing process is performed on the third space S3 at temperature of 1000° C. to 1500° C., which enables better annealing.

The ion implantation process performed on the third space S3 can result in better conductivity of the third space S3, which can facilitate pickup of electric charge from the body region through the third space S3. In other embodiments of the present application, the ion implantation process performed on the third space S3 may be omitted.

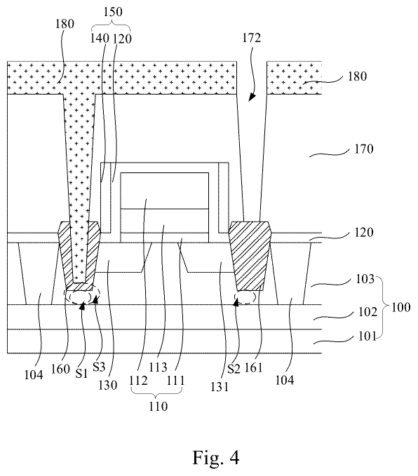

Referring to FIG. 4, in embodiments of the present application, a second opening 172 is then formed in the interlayer dielectric layer 170. The second opening 172 penetrates through the interlayer dielectric layer 170, and exposes the drain 161. Specifically, a patterned photoresist layer 180 may be formed, which fills the first opening 171 and covers a portion of the interlayer dielectric layer 170. Moreover, in the patterned photoresist layer 180, there is also an opening exposing a portion of the interlayer dielectric layer 170 aligned with the drain 161. The interlayer dielectric layer 170 may be then etched to form the second opening 172. The etching may stop at a surface of the drain 161, exposing the drain 161. Subsequently, the patterned photoresist layer 180 may be stripped away, in particular, using an ashing technique.

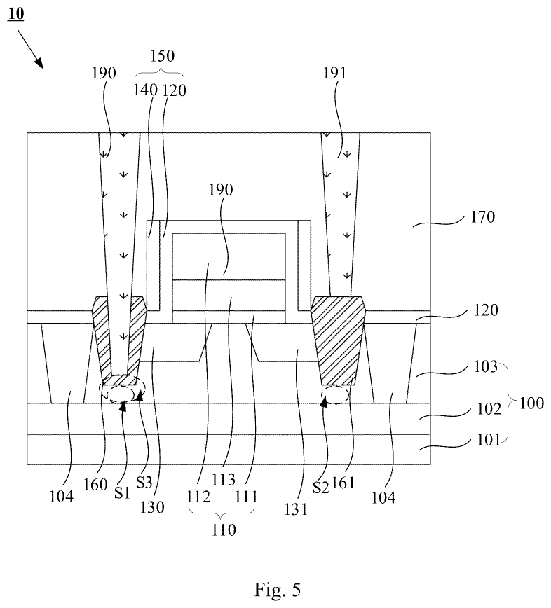

After that, as shown in FIG. 5, a conductive material is filled in the first opening 171 and the second opening 172 to form a source contact structure 190 and a drain contact structure 191. The source contact structure 190 is connected to the source 160, and the drain contact structure 191 is connected to the drain 161. The source contact structure 190 extends into the source 160 and the third space S3 is provided between the top surface of the buried oxide layer 102 and the source contact structure. That is, the conductive material completely fills the first opening 171 to form the source contact structure 190, correspondingly, the third space S3 is provided between the source contact structure 190 and the top surface of the buried oxide layer 102. In embodiments of the present application, electric charge can be picked up from the body region through the third space and the source contact structure. This avoids the FBE problem and enables the PDSOI transistor to have improved quality and reliability.

Correspondingly, embodiments of this application also provide a PDSOI transistor. Referring to FIG. 5, the PDSOI transistor 10 includes: an SOI substrate 100 including a bottom silicon layer 101, a buried oxide layer 102 formed on the bottom silicon layer 101 and a top silicon layer 103 formed on the buried oxide layer 102; a gate structure 110 formed on the SOI substrate 100; a source 160 and a drain 161 formed in the top silicon layer 101 on opposite sides of the gate structure 110, a first space S1 is provided between a bottom surface of the source 160 and a top surface of the buried oxide layer 102, a second space S2 is provided between a bottom surface of the drain 161 and the top surface of the buried oxide layer 102; and a source contact structure 190 and a drain contact structure 191, the source contact structure 190 is connected to the source 160, the drain contact structure 191 is connected to the drain 161, wherein the source contact structure 190 extends into the source 160 and a third space S3 is provided between the top surface of the buried oxide layer 102 and the source contact structure 190.

Preferably, each of the first space S1 and the second space S2 has a dimension greater than 5 nm in a thickness direction of the SOI substrate 100. The third space S3 has a dimension ranging from 5 nm to 15 nm in the thickness direction of the SOI substrate 100.

In embodiments of the present application, the third space S3 contains doping ions. In case of an NMOS device, the doping ions may be boron ions. In case of a PMOS device, the doping ions may be phosphorus ions. As shown in FIG. 5, in embodiments of the present application, the third space S3 may include the first space S1 and a portion of the source 160 between the source contact structure 190 and the first space S1.

The description presented above is merely that of some preferred embodiments of the present invention and is not intended to limit the scope thereof in any sense. Any and all changes and modifications made by those of ordinary skill in the art based on the above teachings fall within the scope of the invention.

1. A partially depleted silicon-on-insulator (PDSOI) transistor, comprising:
a silicon-on-insulator (SOI) substrate, wherein the SOI substrate comprises a bottom silicon layer, a buried oxide layer formed on the bottom silicon layer and a top silicon layer formed on the buried oxide layer;
a gate structure formed on the SOI substrate;
a source and a drain formed in the top silicon layer on opposite sides of the gate structure, wherein a first space is provided between a bottom surface of the source and a top surface of the buried oxide layer and wherein a second space is provided between a bottom surface of the drain and the top surface of the buried oxide layer; and
a source contact structure and a drain contact structure, wherein the source contact structure is connected to the source, wherein the drain contact structure is connected to the drain, and wherein the source contact structure extends into the source and a third space is provided between the source contact structure and the top surface of the buried oxide layer.

2. The PDSOI transistor of claim 1, wherein the third space contains doping ions.

3. The PDSOI transistor of claim 2, wherein the PDSOI transistor is an NMOS device, and the doping ions are boron ions; or
wherein the PDSOI transistor is a PMOS device, and wherein the doping ions are phosphorus ions.

4. The PDSOI transistor of claim 1, wherein the third space includes the first space.

5. The PDSOI transistor of claim 4, wherein the third space further includes a portion of the source between the source contact structure and the first space.

6. The PDSOI transistor of claim 1, wherein each of the first space and the second space has a dimension greater than 5 nm in a thickness direction of the SOI substrate.

7. The PDSOI transistor of claim 1, wherein the third space has a dimension ranging from 5 nm to 15 nm in a thickness direction of the SOI substrate.

8. A method for fabricating a partially depleted silicon-on-insulator (PDSOI) transistor, comprising:
providing a silicon-on-insulator (SOI) substrate, wherein the SOI substrate comprises a bottom silicon layer, a buried oxide layer formed on the bottom silicon layer and a top silicon layer formed on the buried oxide layer;
forming a gate structure on the SOI substrate;
forming a source and a drain in the SOI substrate, wherein the source and the drain are formed in the top silicon layer on opposite sides of the gate structure, wherein a first space is provided between a bottom surface of the source and a top surface of the buried oxide layer, and wherein a second space is provided between a bottom surface of the drain and the top surface of the buried oxide layer;
forming an interlayer dielectric layer on the SOI substrate, wherein the interlayer dielectric layer covers each of the gate structure and the SOI substrate; and
forming a source contact structure and a drain contact structure in the interlayer dielectric layer, wherein the source contact structure is connected to the source, wherein the drain contact structure is connected to the drain, and wherein the source contact structure extends into the source and a third space is provided between the source contact structure and the top surface of the buried oxide layer.

9. The method of claim 8, further comprising, before the source contact structure and the drain contact structure are formed in the interlayer dielectric layer:
forming a first opening in the interlayer dielectric layer, wherein the interlayer dielectric layer penetrates through the interlayer dielectric layer and extends into the source, and wherein the third space is provided between a bottom surface of the first opening and the top surface of the buried oxide layer;
performing an ion implantation process on the third space through the first opening so that the third space contains doping ions; and
forming a second opening in the interlayer dielectric layer, wherein the interlayer dielectric layer extends through the interlayer dielectric layer and exposes the drain, wherein the first opening and the second opening are filled with a conductive material, thereby forming the source contact structure and the drain contact structure.

10. The method of claim 9, further comprising, after the ion implantation process is performed on the third space through the first opening so that the third space contains doping ions, and before the second opening extending through the interlayer dielectric layer and exposing the drain is formed in the interlayer dielectric layer:
performing a laser annealing process on the third space.
